(19) United States
(12) Patent Application Publication
(10) Pub. No.: US 2025/0006862 A1
(43) Pub. Date: Jan. 2, 2025

(54) SEMICONDUCTOR DEVICE

(71) Applicant: EPISTAR CORPORATION, Hsinchu (TW)

(72) Inventors: Yi-Chieh LIN, Hsinchu (TW); Shih-Chang LEE, Hsinchu (TW); Kuo-Feng HUANG, Hsinchu (TW); Shih-Hao CHENG, Hsinchu (TW)

(21) Appl. No.: 18/756,730

(22) Filed: Jun. 27, 2024

(30) Foreign Application Priority Data
Jun. 29, 2023 (TW) 112124219

(51) Int. Cl. H01L 33/06; H01L 31/0232; H01L 31/0236; H01L 31/0304; H01L 31/0352; H01L 33/22; H01L 33/32; H01L 33/46; H01S 5/343

(52) U.S. Cl. CPC H01L 33/06; H01L 31/02327; H01L 31/02363; H01L 31/03046; H01L 31/035236; H01L 33/22; H01L 33/32; H01L 33/46; H01S 5/34306

(57) ABSTRACT

A semiconductor device is provided, which includes a first semiconductor structure, a second semiconductor structure, and an active region. The active region is located between the first semiconductor structure and the second semiconductor structure. The active region includes a light-emitting region having N pair(s) of semiconductor stack(s). Each of the semiconductor stack includes a well layer and a barrier layer, in which N is a positive integer greater than or equal to 1. The well layer includes a first group III-V semiconductor material including indium with a first percentage of indium content. The barrier layer includes a second group III-V semiconductor material including indium with a second percentage of indium content. The first group III-V semiconductor material and the second group III-V semiconductor material further includes phosphorus. The second percentage of indium content is less than the first percentage of indium content.

### CROSS REFERENCE TO RELATED APPLICATIONS

This application claims the right of priority based on TW application No. 112124219, filed on Jun. 29, 2023, which is incorporated by reference herein in its entirety.

### FIELD OF DISCLOSURE

The present disclosure relates to a semiconductor device, in particular, to a semiconductor optoelectronic device.

### BACKGROUND OF THE DISCLOSURE

Nowadays, semiconductor devices are used in a wide range of applications. In recent years, related materials and products have been under development and research. For example, group III-V semiconductor materials including group III and group V elements may be used in various optoelectronic semiconductor devices, such as light-emitting diodes, laser diodes, photodetectors or solar cells, or may be used in power devices, such as switching devices or rectifiers, and may be applied in lighting, medical, display, communication, sensing, power supply system and other fields. As one of the semiconductor light-emitting devices, light-emitting diodes may have the advantages of low energy consumption, fast response speed, small size, and long operating lifetime. Therefore, they are widely used in various fields.

### SUMMARY OF THE DISCLOSURE

The present disclosure provides a semiconductor device. The semiconductor device includes a first semiconductor structure, a second semiconductor structure, and an active region. The active region is located between the first semiconductor structure and the second semiconductor structure. The active region includes a light-emitting region having N pair(s) of semiconductor stack(s). Each of the semiconductor stack includes a well layer and a barrier layer, in which N is a positive integer greater than or equal to 1. The well layer includes a first group III-V semiconductor material including indium with a first percentage of indium content. The barrier layer includes a second group III-V semiconductor material including indium with a second percentage of indium content. The first group III-V semiconductor material and the second group III-V semiconductor material further includes phosphorus. The second percentage of indium content is less than the first percentage of indium content.

### BRIEF DESCRIPTION OF THE DRAWINGS

FIG. 1A shows a schematic sectional view of a semiconductor device in accordance with an embodiment of the present disclosure.

FIG. 1B shows a partial enlarged schematic view of a region R in the semiconductor device of FIG. 1A

FIG. 1C shows an electron microscope diagram and element analysis diagram of a portion of the region R as shown in FIG. 1B.

FIG. 1D shows a relationship between current density and light-emitting efficiency of semiconductor devices having well layers with different indium contents.

FIG. 2A shows a schematic view of the energy band relationship of the active region in the semiconductor device of an embodiment of the present disclosure.

FIG. 2B shows a schematic view of the energy band of the active region in the semiconductor device according to an embodiment of the present disclosure.

FIG. 2C shows a schematic view of the energy band of the active region in the semiconductor device according to an embodiment of the present disclosure.

FIG. 2D shows a schematic view of the energy band of the active region in the semiconductor device according to an embodiment of the present disclosure.

FIG. 3A shows a schematic top view of a semiconductor device according to an embodiment of the present disclosure.

FIG. 3B shows a schematic sectional view of the semiconductor device of FIG. 3A along X-X′ line.

FIG. 4A shows a schematic top view of a semiconductor device according to an embodiment of the present disclosure.

FIG. 4B shows a schematic sectional view of the semiconductor device of FIG. 4A along Y-Y′ line.

FIG. 5A shows a schematic top view of a semiconductor device according to an embodiment of the present disclosure.

FIG. 5B shows a schematic sectional view of the semiconductor device of FIG. 5A along A-A′ line.

FIG. 6A shows a schematic top view of a semiconductor device according to an embodiment of the present disclosure.

FIG. 6B shows a schematic sectional view of the semiconductor device of FIG. 6A along B-B′ line.

FIG. 7 shows a schematic sectional view of a semiconductor component in accordance with an embodiment of the present disclosure.

FIG. 8 shows a schematic sectional view of a semiconductor component in accordance with an embodiment of the present disclosure.

### DETAILED DESCRIPTION OF THE DISCLOSURE

The following embodiments will be described with accompany drawings to disclose the concept of the present disclosure. In the drawings or description, same or similar portions are indicated with same or similar numerals. Furthermore, a shape or a size of a member in the drawings may be enlarged or reduced. Particularly, it should be noted that a member which is not illustrated or described in drawings or description may be in a form that is known by a person skilled in the art.

The semiconductor device of the present disclosure is, for example, a light-emitting device (such as a light-emitting diode or a laser diode), a light absorbing device (such as a photo-detector) or a non-illumination device. The qualitative or quantitative analysis of the composition and/or dopant contained in each layer of the semiconductor device of the present disclosure may be conducted by any suitable method, for example, a secondary ion mass spectrometer (SIMS). A thickness of each layer may be obtained by any suitable method, such as a transmission electron microscopy (TEM) or a scanning electron microscope (SEM).

Those with ordinary knowledge in the art should understand that other member(s) may be added on the basis of each embodiment described below. For example, if not otherwise specified, a description similar to “a first layer/structure is on or under a second layer/structure” may include an embodiment in which the first layer/structure is in direct contact with (or physically/directly contacts) the second layer/structure, and may also include an embodiment in which another structure is provided between the first layer/structure and the second layer/structure, such that the first layer/structure and the second layer/structure do not directly contact each other. Furthermore, it should be realized that a positional relationship of a layer/structure may be altered when being observed in different orientations.

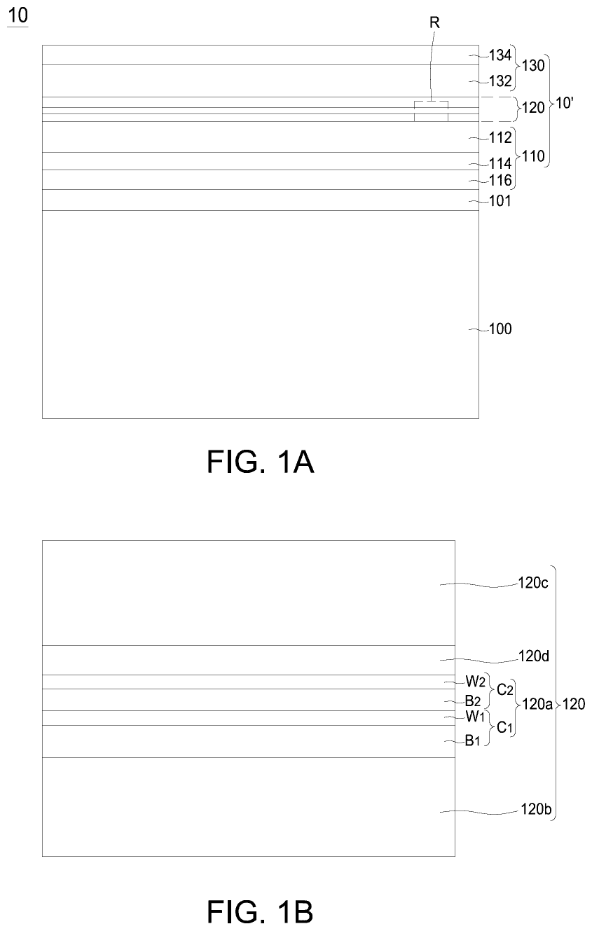

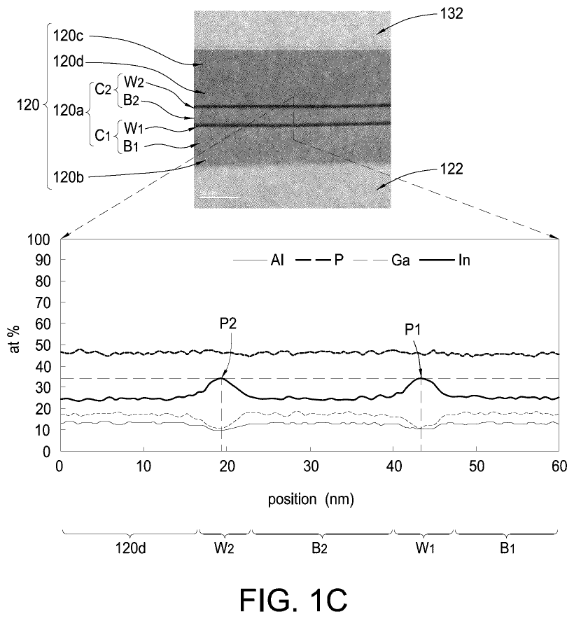

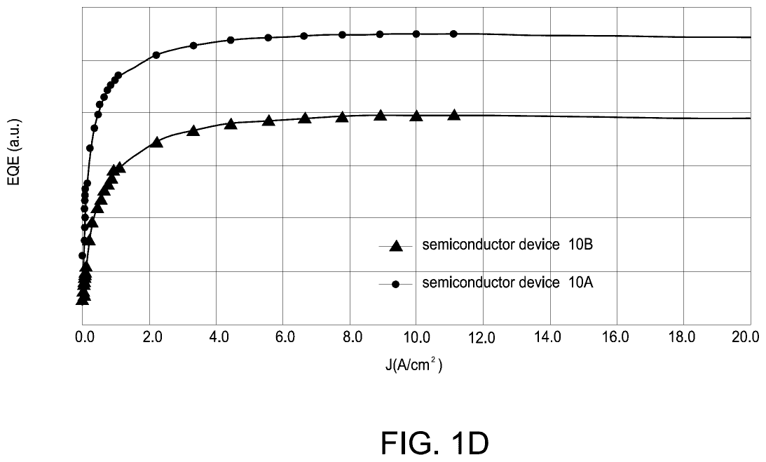

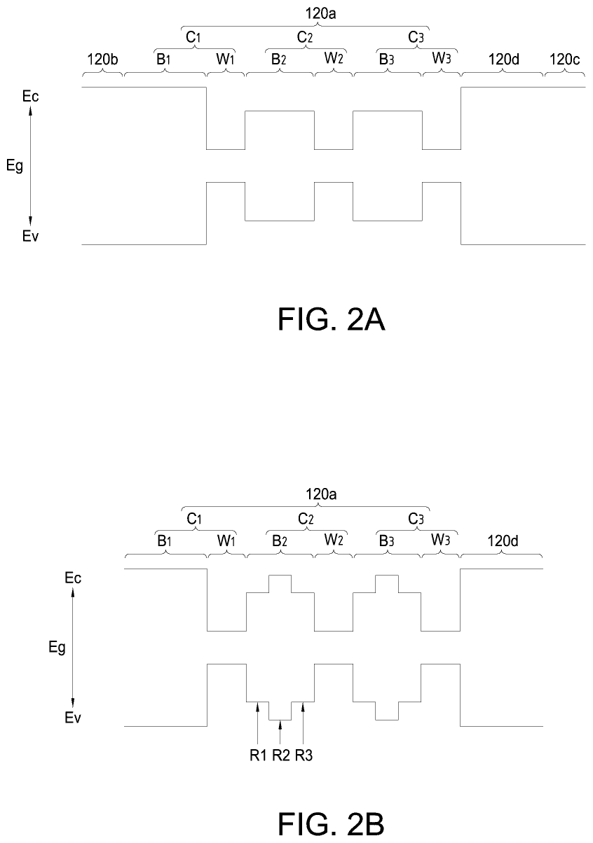

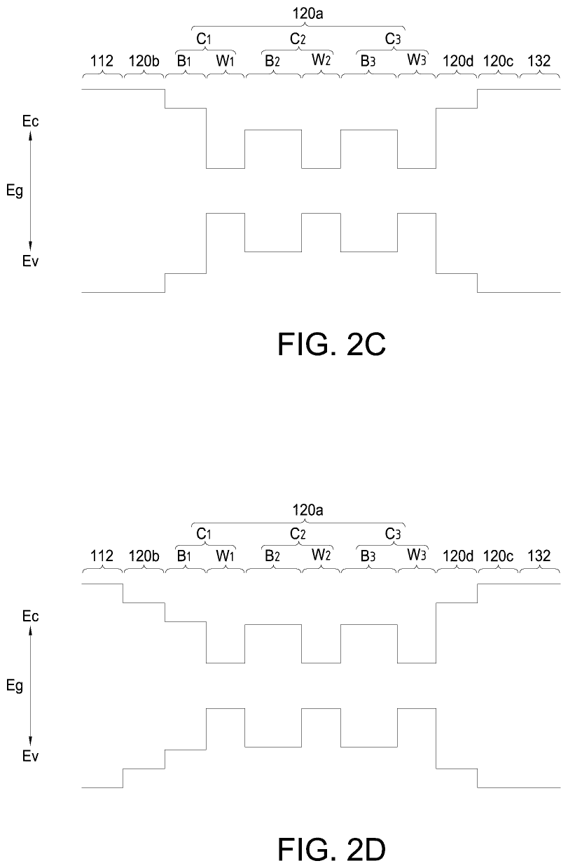

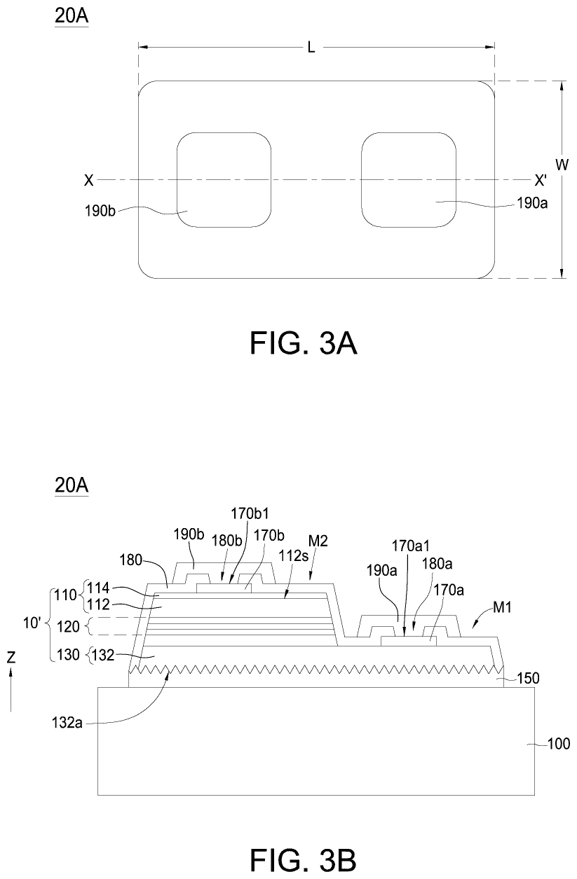

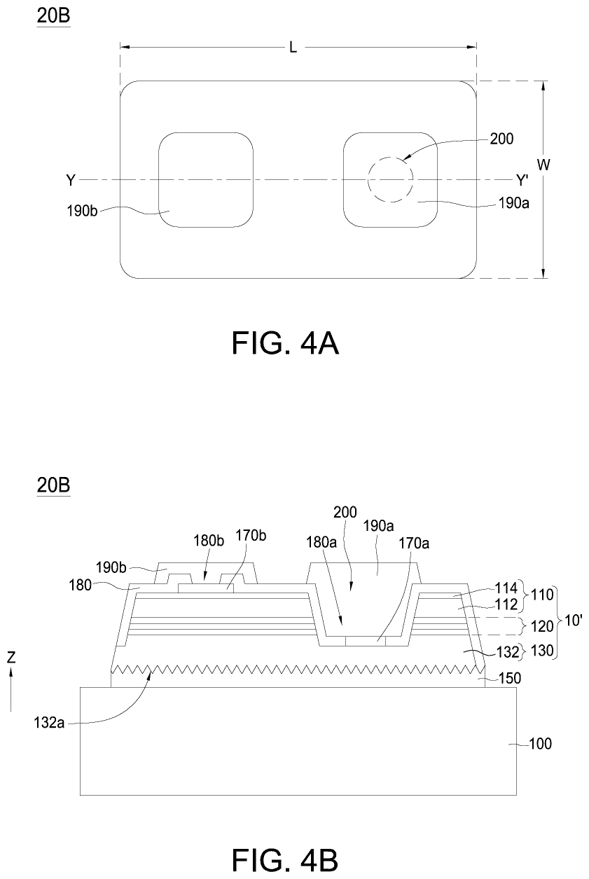

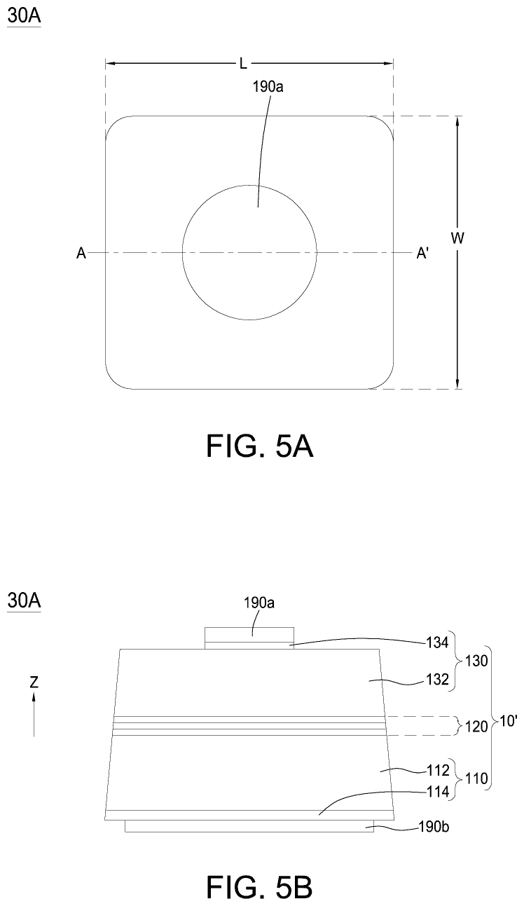

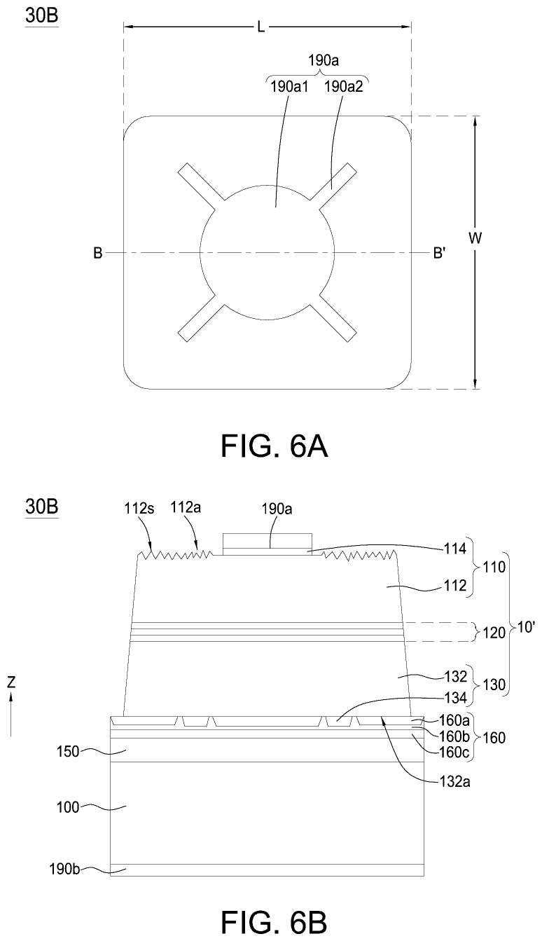

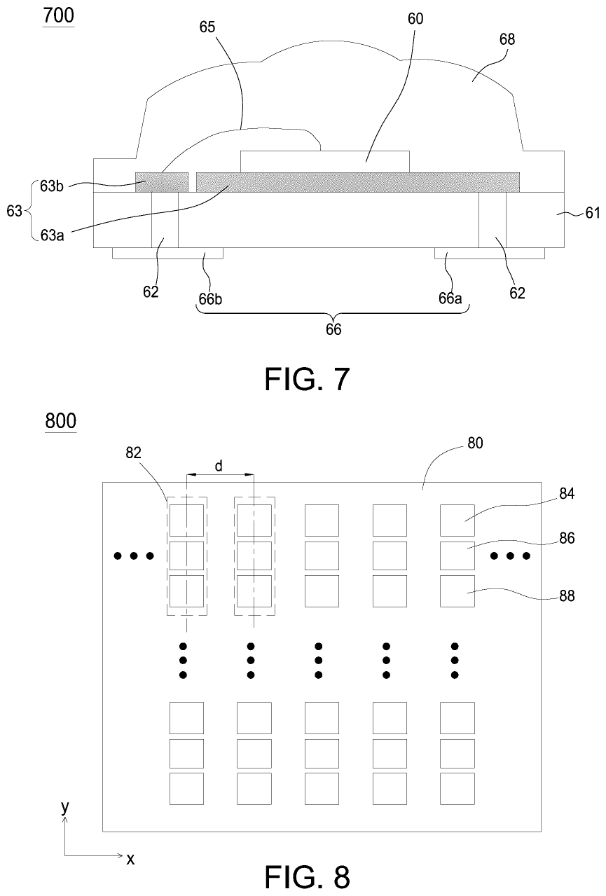

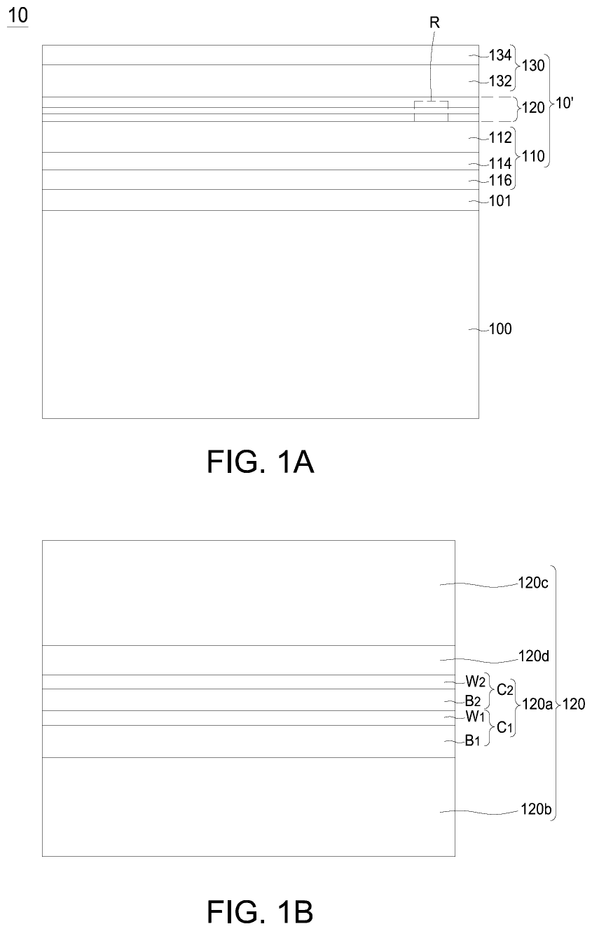

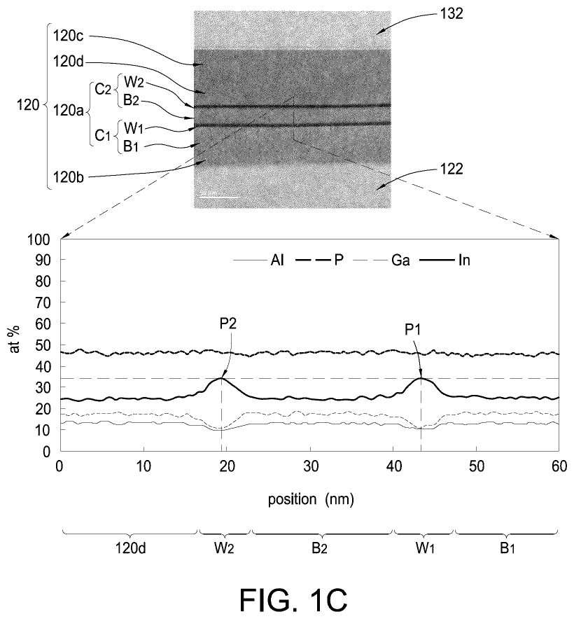

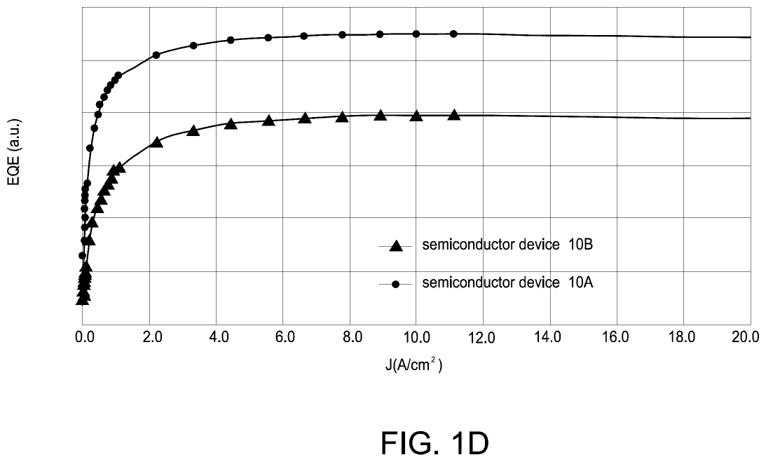

FIG. 1A shows a schematic sectional view of a semiconductor device 10 in accordance with an embodiment of the present disclosure. FIG. 1B shows a partial enlarged schematic view of a region R in the semiconductor device 10 according to an embodiment. As shown in FIGS. 1A and 1B, the semiconductor device 10 includes an epitaxial structure 10′. The epitaxial structure 10′ includes a first semiconductor structure 110, an active region 120 and a second semiconductor structure 130. The active region 120 is located between the first semiconductor structure 110 and the second semiconductor structure 130. The first semiconductor structure 110 and the second semiconductor structure 130 are respectively located on two sides of the active region 120 and are adjacent to the active region 120. The first semiconductor structure 110 and the second semiconductor structure 130 may be single-layer or multi-layer structures. Each of the first semiconductor structure 110, the active region 120 and the second semiconductor structure 130 may include a binary, a ternary or a quaternary group III-V semiconductor material, such as a group III-V semiconductor material including an element or elements containing aluminum (Al), gallium (Ga), arsenic (As), phosphorus (P) or indium (In). According to an embodiment, the first semiconductor structure 110, the active region 120 and the second semiconductor structure 130 do not contain nitrogen (N).

The first semiconductor structure 110 and the second semiconductor structure 130 may have different conductivity types and may respectively provide electrons and holes. For example, the first semiconductor structure 110 is n-type and the second semiconductor structure 130 is p-type, or the first semiconductor structure 110 is p-type and the second semiconductor structure 130 is n-type. The conductivity types of the first semiconductor structure 110 and the second semiconductor structure 130 may be adjusted by adding different dopants. In some embodiments, each dopant may include an element from group II, group IV or group VI of the periodic table, such as magnesium (Mg), zinc (Zn), carbon (C), silicon (Si) or tellurium (Te). When the semiconductor device 10 is a semiconductor light-emitting device, the first semiconductor structure 110 and the second semiconductor structure 130 can respectively provide electrons and holes (or holes and electrons) to the active region 120. Electrons and holes can combine in the active region 120 to emit light of a specific wavelength. The light may include visible light or invisible light, such as yellow, orange or red light with a peak wavelength in a range of 530 nm to 700 nm, or infrared light with a peak wavelength in a range of 700 nm to 1700 nm.

As shown in FIG. 1A, the semiconductor device 10 may optionally include a base 100. In this embodiment, the epitaxial structure 10′ is located on the base 100. The base 100 includes a conductive material or an insulating material. For example, the conductive material includes gallium arsenide (GaAs), indium phosphide (InP), silicon carbide (SiC), gallium phosphide (GaP), zinc oxide (ZnO), and gallium nitride. (GaN), aluminum nitride (AlN), germanium (Ge) or silicon (Si), and the insulating materials includes sapphire, glass, diamond, aluminum nitride (AlN), quartz, acrylic, or epoxy. In an embodiment, the base 100 is a growth substrate, that is, the epitaxial structure 10′ may be formed on the base 100 by metal-organic chemical vapor deposition (MOCVD), for example. In an embodiment, the base 100 may be a bonding substrate instead of a growth substrate, which may be bonded to the epitaxial structure 10′ through an adhesive layer (not shown).

The semiconductor device 10 may optionally include a buffer layer 101 located between the base 100 and the epitaxial structure 10′. When the base 100 is a growth substrate, the buffer layer 101 may compensate the difference in lattice constants between the base 100 and the epitaxial structure 10′, so as to avoid epitaxial defects that extends from the base 100 to the epitaxial structure 10′. According to an embodiment, the buffer layer 101 includes a binary group III-V semiconductor material, such as GaAs or GaN.

As shown in FIG. 1A, in this embodiment, the first semiconductor structure 110 includes a first semiconductor layer 112, and the second semiconductor structure 130 includes a third semiconductor layer 132. The first semiconductor layer 112 and the third semiconductor layer 132 may be cladding layers that can be respectively designated as a first cladding layer and a second cladding layer. The first semiconductor layer 112 and the third semiconductor layer 132 may have different conductivity types and may respectively provide electrons and holes (or holes or electrons). According to an embodiment, the first semiconductor layer 112 and the third semiconductor layer 132 each includes a ternary or a quaternary group III-V semiconductor material. For example, the first semiconductor layer 112 includes AlInP or AlGaInP, and the third semiconductor layer 132 includes AlInP or AlGaInP. In an embodiment, the first semiconductor layer 112 may have a dopant concentration less than 3×10¹⁸ cm⁻³ (such as in a range of more than 1×10¹⁸ cm⁻³ and less than 2×10¹⁸ cm⁻³) to prevent a dopant from diffusing into the active region 120 and affecting the reliability of the semiconductor device 10.

Optionally, the first semiconductor structure 110 includes a second semiconductor layer 114 and a fourth semiconductor layer 134. The second semiconductor layer 114 and the fourth semiconductor layer 134 may be contact layers that can be respectively designated as a first contact layer and a second contact layer so as to form good contacts (such as ohmic contacts) with a metal material. According to an embodiment, materials of the second semiconductor layer 114 and the fourth semiconductor layer 134 may be different, such as arsenide or phosphide. In an embodiment, the second semiconductor layer 114 and the fourth semiconductor layer 134 include binary group III-V semiconductor materials. For example, the second semiconductor layer 114 includes GaAs and the fourth semiconductor layer 134 includes GaP.

As shown in FIG. 1A, the first semiconductor structure 110 may optionally include a fifth semiconductor layer 116. The fifth semiconductor layer 116 may be designated as an etch stop layer. In some embodiments, when the base 100 and the buffer layer 101 need to be removed by etching or grinding, the fifth semiconductor layer 116 can protect an adjacent semiconductor layer (such as the second semiconductor layer 114) from damage. According to an embodiment, the fifth semiconductor layer 116 includes a ternary group III-V semiconductor material such as InGaP.

The active region 120 may include a light-emitting region 120a having N semiconductor stack(s) (or N pairs of semiconductor layers), where N is a positive integer greater than or equal to 1. According to some embodiments, N may be a positive integer less than or equal to 5, such as 2, 3 or 4. Each semiconductor stack in the light-emitting region 120a may respectively be represented by Cₙ, where n=1, 2, 3, . . . , N. Each semiconductor stack Cₙ includes a well layer Wₙ and an adjacent barrier layer Bₙ, where n=1, 2, . . . , N. For example, when N=1, the active region 120 includes a first semiconductor stack C₁, and the first semiconductor stack C₁ has the first barrier layer B₁ and the first well layer W₁; when N=2, the active region 120 includes the first semiconductor stack C₁ and a second semiconductor stack C₂, the first semiconductor stack C₁ has a first barrier layer B₁ and a first well layer W₁, and the second semiconductor stack C₂ has a second barrier layer B₂ and a second well layer W₂. FIG. 1B shows an embodiment in which N=2.

Each of the materials of the well layer Wₙ and the barrier layer Bₙ may include an element or elements containing aluminum (Al), gallium (Ga), arsenic (As), phosphorus (P) or indium (In). According to an embodiment, the well layer Wₙ and the barrier layer Bₙ do not contain nitrogen (N). In an embodiment, the well layer Wₙ includes a first group III-V semiconductor material, and the barrier layer Bₙ includes a second group III-V semiconductor material. In an embodiment, the first group III-V semiconductor material and the second group III-V semiconductor material include elements containing indium (In) and phosphorus (P). In an embodiment, the first group III-V semiconductor material and the second group III-V semiconductor material include elements containing indium (In) and arsenic (As). The first group III-V semiconductor material and the second group III-V semiconductor material may be the same or different, for example, may be the same or different group III-V semiconductor compounds. Here, “the same group III-V semiconductor compound” means that elements constituting the group III-V semiconductor compound are the same, and the content ratios of each element in the compounds do not necessarily have to be the same. In an embodiment, the first group III-V semiconductor material and the second group III-V semiconductor material are quaternary group III-V semiconductor compounds, such as AlGaInP, InGaAsP or AlGaInAs. In an embodiment, the well layer Wₙ in each semiconductor stack Cₙ includes the same quaternary group III-V semiconductor compound (such as AlGaInP, InGaAsP or AlGaInAs). For example, the well layer W1 and the well layer W2 both include AlGaInP. In an embodiment, the barrier layer Bₙ in each semiconductor stack Cₙ includes the same quaternary group III-V semiconductor compound (such as AlGaInP, InGaAsP or AlGaInAs). For example, the barrier layer B₁ and the barrier layer B₂ both include AlGaInP. In an embodiment, the well layer Wₙ and barrier layer Bₙ in each semiconductor stack Cₙ both include the same quaternary group III-V semiconductor compound (such as AlGaInP, InGaAsP or AlGaInAs). For example, the well layer W₁, the well layer W₂, the barrier layer B₁ and the barrier layer B₂ all include AlGaInP.

According to an embodiment, the well layer Wₙ and the base 100 are lattice-mismatched. Here, the base 100 corresponds to a growth substrate such as a gallium arsenide (GaAs) substrate. For example, under X-ray diffraction analysis (XRD) analysis, a degree of lattice mismatch between the well layer Wₙ and the base 100 may be greater than or equal to 5000 ppm, for example, in a range of 5000 ppm to 15000 ppm. In an embodiment, when the lattice mismatch between the well layer Wₙ and the base 100 is greater than or equal to 5000 ppm, the surface recombination may be reduced, which helps to improve the external quantum efficiency (EQE) of the semiconductor device 10. According to an embodiment, the lattice constants of the well layer Wₙ and the barrier layer Bₙ may be controlled, for example, by adjusting percentages of indium content in the well layer Wₙ and the barrier layer Bₙ.

In an embodiment, the first group III-V semiconductor material and the second group III-V semiconductor material have different percentages of indium content. For example, the first group III-V semiconductor material has a first percentage of indium content, and the second group III-V semiconductor material has a second percentage of indium content less than the first percentage of indium content. The first percentage of indium content may be defined as a percentage of indium content in all group III elements of the first group III-V semiconductor material, and the second percentage of indium content may be defined as the percentage of indium content in all group III elements of the second group III-V semiconductor material. The first percentage of indium content may be greater than or equal to 55%, for example, in a range of 55% to 85%. The second percentage of indium content may be greater than or equal to 45%, for example, in a range of 45% to 55%. In an embodiment, the first percentage of indium content is greater than the second percentage of indium content, and a difference between the first percentage of indium content and the second percentage of indium content may be greater than or equal to 10%, for example, in a range of 10% to 30%. According to an embodiment, by adjusting the first percentage of indium content, the second percentage of indium content, and/or the difference between the first percentage of indium content and the second percentage of indium content, the surface recombination may be effectively reduced and the photoelectric conversion efficiency of the active region 120 may be improved.

In an embodiment, the first group III-V semiconductor material and the second group III-V semiconductor material may be the same quaternary group III-V semiconductor compound but have different percentages of indium content. For example, the well layer Wₙ contains (Alₓ₁Ga₁₋ₓ₁)_{1-y1}In_{y1}P, and the barrier layer Bₙ contains (Alₓ₂Ga₁₋ₓ₂)_{1-y2}In_{y2}P, where y1 is not equal to y2, for example, y2 is less than y1. According to an embodiment, 0<x1,x2,y1,y2<1.

The first percentage of indium content and the second percentage of indium content may be obtained, for example, by using an energy dispersive spectrometer (EDX) to analyze the barrier layer Bₙ and the well layer Wₙ respectively, then calculating the percentage of indium content (In %) in the barrier layer Bₙ and the percentage of indium content (In %) in the well layer Wₙ. For example, the well layer Wₙ contains (Alₓ₁Ga₁₋ₓ₁)_{1-y1}In_{y1}P, and the barrier layer Bₙ contains (Alₓ₂Ga₁₋ₓ₂)_{1-y2}In_{y2}P. Atomic percentages (at %) of Al, Ga, In and P may be obtained by EDX analysis, from which x1, x2, y1 and y2 can be calculated. Specifically, y1 may be obtained by dividing the atomic percentage of indium (In) in the well layer Wₙ by the atomic percentage of the group V element (i.e., phosphorus (P)) in the well layer Wₙ, and x1 may be obtained by dividing the atomic percentage of aluminum (Al) in the well layer Wₙ by the sum of atomic percentages of aluminum (Al) and gallium (Ga) in the group III elements in the well layer Wₙ; y2 may be obtained by dividing the atomic percentage of indium (In) in the barrier layer Bₙ by the atomic percentage of the group V element (i.e., phosphorus (P)) in the barrier layer Bₙ, and x2 may be obtained by dividing the atomic percentage of aluminum (Al) in the barrier layer Bₙ by the sum of atomic percentages of aluminum (Al) and gallium (Ga) in the group III elements in the barrier layer Bₙ. Here, the percentage of indium content (In %) of the well layer Wₙ may be defined as y1*100% (i.e., the first percentage of indium content), and the percentage of indium content (In %) of the barrier layer Bₙ may be defined as y2*100% (i.e., the second percentage of indium content).

According to an embodiment, the first group III-V semiconductor material and the second group III-V semiconductor material have different percentages of gallium content. For example, the first group III-V semiconductor material has a first percentage of gallium content, and the second group III-V semiconductor material has a second percentage of gallium content greater than the first percentage of gallium content. The first percentage of gallium content may be defined as a percentage of gallium content in total content of aluminum and gallium in the group III elements of the first group III-V semiconductor material. The second percentage of gallium content may be defined as a percentage of gallium content in total content of aluminum and gallium in the group III elements of the second group III-V semiconductor material. The first percentage of gallium content and the second percentage of gallium content may be calculated from EDX analysis results. EDX measurements may be performed respectively on the barrier layer Bₙ and the well layer Wₙ to obtain the atomic percentages of each element, and then the first percentage of gallium content and second percentage of gallium content may be calculated. Specifically, the first percentage of gallium content (Ga %) may be obtained by dividing the atomic percentage of gallium (Ga) by the sum of atomic percentages of aluminum (Al) and gallium (Ga) in the group III elements in the well layer Wₙ and multiplying the result by 100%. The second percentage of gallium content (Ga %) may be obtained by dividing the atomic percentage of gallium (Ga) by the sum of atomic percentages of aluminum (Al) and gallium (Ga) in the group III elements in the barrier layer Bₙ and multiplying the result by 100%. For example, the well layer Wₙ contains (Alₓ₁Ga₁₋ₓ₁)_{1-y1}In_{y1}P, and the barrier layer Bₙ contains (Alₓ₂Ga₁₋ₓ₂)_{1-y2}In_{y2}P, the first percentage of gallium content (Ga %) may be defined as (1−x1)*100%, and the second percentage of gallium content (Ga %) may be defined as (1−x2)*100%. In an embodiment, the first percentage of gallium content may be greater than or equal to 25%, for example, in a range of 25% to 100%. In an embodiment, the second percentage of gallium content may be greater than or equal to 0%, for example, in a range of 0% to 50%. According to an embodiment, when the first percentage of gallium content is greater than 40%, the semiconductor device 10 can further have a higher brightness and a narrower half-maximum width (FWHM).

The thickness of the barrier layer Bₙ may be greater than the thickness of the well layer Wₙ. In an embodiment, the thickness of the barrier layer Bₙ may be at least 2.5 times the thickness of the well layer Wₙ, for example, in a range of 2.5 times to 10 times. According to an embodiment, when the thickness of the barrier layer Bₙ is at least 2.5 times the well layer Wₙ, it helps to reduce a stress in the epitaxial structure 10′ and further improve the quality of the epitaxial structure 10′. In an embodiment, in one or more semiconductor stacks Cₙ in the light-emitting region 120a, a ratio of the thickness of the barrier layer Bₙ to the thickness of the well layer Wₙ is in a range of greater than or equal to 2.5 and less than or equal to 10. According to an embodiment, when the ratio of the thickness of the barrier layer Bₙ to the thickness of the well layer Wₙ is in a range of greater than or equal to 2.5 and less than or equal to 10, the semiconductor device 10 can have higher brightness and narrower half-maximum width (FWHM). In an embodiment, the ratio of the thickness of the barrier layer Bₙ to the thickness of the well layer Wₙ in each semiconductor stack Cₙ in the light-emitting region 120a is in a range of greater than or equal to 2.5 and less than or equal to 10. According to an embodiment, the thickness of the barrier layer Bₙ may be greater than or equal to 100 Å, for example, in a range of 100 Å to 400 Å. According to an embodiment, the thickness of the well layer Wₙ may be less than or equal to 50 Å, for example, in a range of 20 Å to 50 Å. According to an embodiment, when the thicknesses of the barrier layer Bₙ and well layer Wₙ are within the above ranges, the semiconductor device 10 can have a higher brightness and a narrower half-maximum width (FWHM) as the thickness of barrier layer Bₙ increases.

As shown in FIG. 1A and FIG. 1B, the active region 120 may optionally include a first confinement layer 120b and a second confinement layer 120c, which are located on two sides of the light-emitting region 120a. In an embodiment, the first confinement layer 120b and the second confinement layer 120c respectively include a ternary or quaternary group III-V semiconductor material, such as AlInP or AlGaInP. In an embodiment, the first confinement layer 120b and the second confinement layer 120c may have a bandgap greater than or equal to the barrier layer Bₙ, thereby increasing the probability of carrier recombination for light emission. According to an embodiment, the percentage of aluminum content (Al %) in the first confinement layer 120b and the second confinement layer 120c may be in a range of 75% to 100% to increase carrier recombination efficiency and to improve the reliability of the semiconductor device 10. The percentage of aluminum content (Al %) may be defined as a percentage of aluminum content in total content of aluminum and gallium in the group III elements. For example, the percentage of aluminum content (Al %) may be calculated from the EDX analysis results: EDX measurements may be performed on the first confinement layer 120b and the second confinement layer 120c to obtain the atomic percentages of each element, and then the percentage of aluminum content (Al %) may be calculated. Specifically, the percentage of aluminum content (Al %) may be obtained by dividing the atomic percentage of aluminum (Al) by the sum of the atomic percentages of aluminum (Al) and gallium (Ga) in the group III elements and then multiplying the result by 100%. For example, when the first confinement layer contains (Alₓ₃Ga₁₋ₓ₃)_{1-y3}In_{y3}P, the percentage of aluminum content (Al %) may be defined as x3*100%; when the first confinement layer contains Alₓ₄In_{y4}P, the percentage of aluminum content (Al %) may be defined as 100%. According to an embodiment, 0<x3,x4,y3,y4<1. The thicknesses of the first confinement layer 120b and the second confinement layer 120c may be greater than the thickness of the barrier layer Bₙ. In an embodiment, the thickness of the first confinement layer 120b (or the second confinement layer 120c) may be at least 2 times the thickness of the barrier layer Bn, for example, in a range of 2 times to 10 times. When the thickness relationships between the first confinement layer 120b (or the second confinement layer 120c) and the barrier layer Bn is within the above ranges, the capability of confining carriers may be improved and the reliability of the semiconductor device 10 may be improved. In an embodiment, the thickness of the first confinement layer 120b (or the second confinement layer 120c) may be greater than or equal to 200 Å, for example, in a range of 200 Å to 1000 Å. In an embodiment, when the thickness of the first confinement layer 120b (or the second confinement layer 120c) is within the above ranges, the efficiency and reliability of the semiconductor device 10 may be further improved.

The active region 120 may optionally include an additional barrier layer 120d located between the light-emitting region 120a and the second confinement layer 120c. The material of the additional barrier layer 120d may include an element or elements containing aluminum (Al), gallium (Ga), arsenic (As), phosphorus (P) or indium (In). According to an embodiment, the additional barrier layer 120d does not contain nitrogen (N). The additional barrier layer 120d and the barrier layer Bₙ may have the same material such as the second group III-V semiconductor material. As shown in FIG. 1B, the additional barrier layer 120d is adjacent to the well layer Wₙ in the N^{th} semiconductor stack. Specifically, the additional barrier layer 120d may have a bandgap greater than the well layer Wₙ to increase the probability of carrier recombination for light emission.

FIG. 1C shows an electron microscope diagram and element analysis diagram of a portion of the region R as shown in FIG. 1B. In this embodiment, the well layer Wₙ and barrier layer Bₙ include Al, Ga, In and P. As shown in FIG. 1C, the atomic percentage (at %) of indium (In) can have a peak value at a position corresponding to the well layer Wₙ. Specifically, the atomic percentage (at %) of indium (In) in the first well layer W₁ reaches a first peak value P1, and the atomic percentage (at %) of indium (In) in the second well layer W₂ reaches a second peak value P2. In some embodiments, the first peak value P1 and the second peak value P2 may be the same, or the first peak value P1 and the second peak value P2 may be different, and the difference between the first peak value P1 and the second peak value P2 is 5 at % or less. As shown in FIG. 1C, the atomic percentage of indium (In) gradually increases from the first barrier layer B₁ to the first well layer W₁ and reaches the first peak value P1, and from the first well layer W₁ to the second barrier layer B₁, the atomic percentage of indium (In) gradually decreases from the first peak value P1. The atomic percentage of indium (In) gradually increases from the second barrier layer B₂ to the second well layer W₂ and reaches the second peak value P2, and from the second well layer W₂ to the additional barrier layer 120d, the atomic percentage of indium (In) gradually decreases from the second peak value P2. In this embodiment, the first barrier layer B₁ and the first confinement layer 120b may include the same group III-V semiconductor compound, so an interface between the first barrier layer B₁ and the first confinement layer 120b may be less obvious. Similarly, the additional barrier layer 120d and the second confinement layer 120c may have the same group III-V semiconductor compound, so the interface between the additional barrier layer 120d and the second confinement layer 120c may be less obvious. As mentioned above, the percentage of indium content (In %) may be calculated by the atomic percentage of indium (In). In this embodiment, the difference between the maximum value and the minimum value of the percentage of indium content (In %) in the active region 120 may be 20% or more.

FIG. 1D shows a relationship between current density and light-emitting efficiency of semiconductor devices having well layers with different indium contents. In this embodiment, the semiconductor device 10A has a structure of the active region 120 (N=2) as shown in FIG. 1C. Both the well layer Wₙ and the barrier layer Bₙ include AlGaInP, where the difference between the percentage of indium content (In %) in the well layer Wₙ and the percentage of indium content (In %) in the barrier layer Bₙ may be 20%+10%. The active region 120 of the semiconductor device 10B also has 2 semiconductor stacks, in which both the well layer Wₙ and the barrier layer Bₙ contain AlGaInP, and the difference between the percentage of indium content (In %) in the well layer Wₙ and the percentage of indium content (In %) in the barrier layer Bₙ may be 5% or less. As shown in FIG. 1D, under different current densities (for example, under current densities of 1 A/cm² to 20 A/cm²), the semiconductor device 10A has better external quantum efficiency (EQE) performance compared with the semiconductor device 10B.

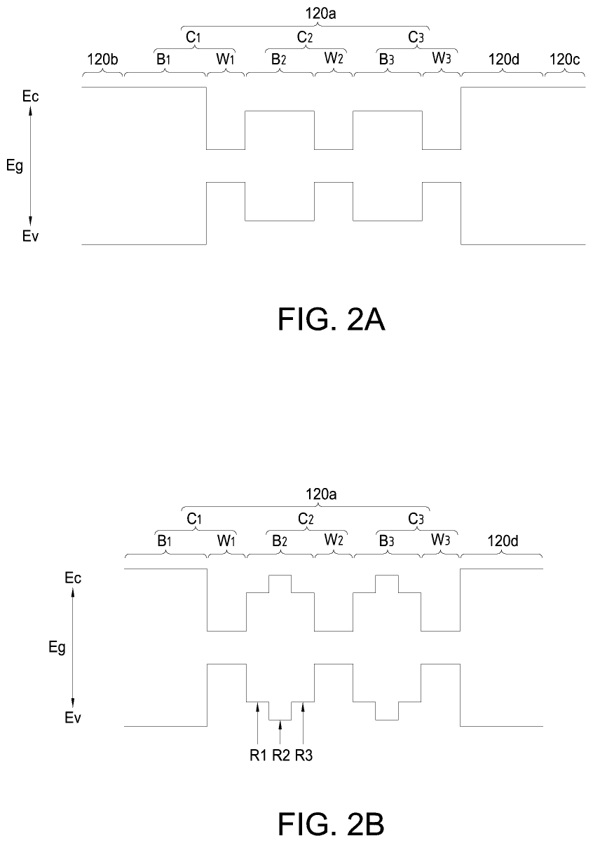

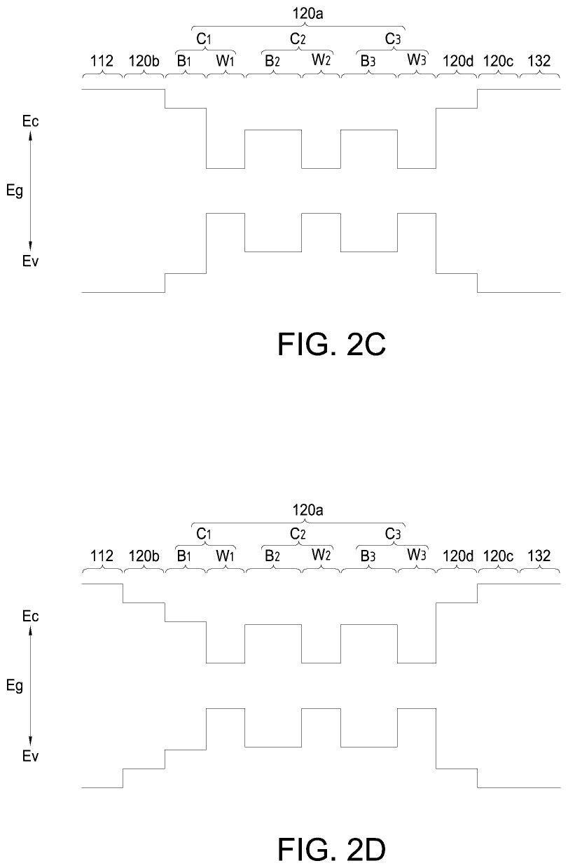

FIG. 2A shows a schematic view of the energy band relationship (or bandgap relationship) of the active region 120 in the semiconductor device 10 of an embodiment of the present disclosure. Specifically, FIG. 2A shows a light-emitting region 120a with 3 semiconductor stacks (i.e., an embodiment of N=3). Therefore, the active region 120 includes the first semiconductor stack C₁, the second semiconductor stack C₂, and the third semiconductor stack C₃. The first semiconductor stack C₁ has a first barrier layer B₁ and a first well layer W₁, the second semiconductor stack C₂ has a second barrier layer B₂ and a second well layer W₂, the third semiconductor stack C₃ has a third barrier layer B₃ and a third well layer W3, and the active region 120 further includes an additional barrier layer 120d adjacent to the third well layer W3. As shown in FIG. 2A, the first confinement layer 120b and the second confinement layer 120c are adjacent to the first barrier layer B₁ and the additional barrier layer 120d, respectively. In this embodiment, the bandgap (or energy gap, Eg) of the first barrier layer B₁ is greater than the bandgap of the second barrier layer B₂ and greater than the bandgap of the third barrier layer B₃. The bandgap of the additional barrier layer 120d is greater than the bandgap of the second barrier layer B₂ and greater than the bandgap of the third barrier layer B₃. The bandgap of the second barrier layer B₂ is greater than the bandgap of any well layer, and the bandgap of the third barrier layer B₃ is greater than the bandgap of any well layer. The above bandgap corresponds to an energy difference between the highest energy level of the valence band (Ev) and the lowest energy level of the conduction band (Ec). In this embodiment, by making the bandgap of the barrier layer that is closest to the first confinement layer 120b and the bandgap of the barrier layer that is closest to the second confinement layer 120c greater than the bandgaps of other barrier layers in the active region 120, the carrier recombination efficiency may be improved, and the reliability of the semiconductor device 10 may be improved.

For example, in each layer in the active region 120, the bandgap size of each layer may be changed by adjusting the percentage of aluminum content (Al %). In an embodiment, the first barrier layer B₁ and the additional barrier layer 120d have a first percentage of aluminum content, the second barrier layer B₂ and the third barrier layer B₃ have a second percentage of aluminum content less than the first percentage of aluminum content, and any well layer has a third percentage of aluminum content less than the second percentage of aluminum content. For example, the first percentage of aluminum content may be in a range of 50% to 100%, and the second percentage of aluminum content may be in a range of 40% to 75%. The difference between first percentage of aluminum content and second percentage of aluminum content may be in a range of 10% to 30%. In an embodiment, the third percentage of aluminum content may be in a range of 50% to 100%.

FIG. 2B shows a schematic view of the energy band of the active region 120 in the semiconductor device 10 according to an embodiment of the present disclosure. FIG. 2B shows a light-emitting region 120a with three semiconductor stacks (i.e., an embodiment of N=3). The difference between the embodiments in FIG. 2B and FIG. 2A is that there are varied bandgaps in the second barrier layer B₂ and the third barrier layer B₃ in FIG. 2B. Taking the second barrier layer B₂ as an example, the second barrier layer B₂ may include the first area R1, the second area R2 and the third area R3 in order. The bandgap of the second area R2 is greater than the bandgap of the first area R1, and the bandgap of the second area R2 is greater than the bandgap of the third area R3. For example, the bandgap size of each area may be changed by adjusting the percentage of aluminum content (Al %) of different areas in the second barrier layer B₂ and the third barrier layer B₃. For example, the percentage of aluminum content (Al %) of the second area R2 is greater than the percentage of aluminum content (Al %) of the first area R1, and the percentage of aluminum content (Al %) of the second area R2 is greater than the percentage of aluminum content (Al %) of the third area R3. In an embodiment, the difference between the maximum value and the minimum value of the percentage of aluminum content (Al %) in the second barrier layer B₂ may be in a range of 10% to 50%, and the difference between the maximum value and the minimum value of the percentage of aluminum content (Al %) in the third barrier layer B₃ may be in a range of 10% to 50%. For example, the percentage of aluminum content (Al %) of the second area R2 may be in a range of 50% to 100%, the percentage of aluminum content (Al %) of the first area R1 and the percentage of aluminum content (Al %) of the third area R3 may be respectively in a range of 40% to 75%. In this embodiment, by having varied bandgaps in a single barrier layer, carrier recombination efficiency may be improved, which helps to increase the brightness of the semiconductor device 10. In this embodiment, both the second barrier layer B₂ and the third barrier layer B₃ have varied bandgaps. In another embodiment, one of the second barrier layer B₂ and the third barrier layer B₃ may have varied bandgaps.

FIG. 2C shows a schematic view of the energy band of the active region 120, the first semiconductor layer 112, and the third semiconductor layer 132 in the semiconductor device 10 according to an embodiment of the present disclosure. FIG. 2C shows a light-emitting region 120a with three semiconductor stacks (i.e., an embodiment of N=3), and further illustrates the first semiconductor layer 112 and the third semiconductor layer 132. In this embodiment, bandgaps of the first confinement layer 120b and the second confinement layer 120c are greater than the bandgap of any barrier layer (i.e., the first barrier layer B₁, the second barrier layer B₂, the third barrier layer B₃ or the additional barrier layer 120d). The bandgaps of the first semiconductor layer 112 and the third semiconductor layer 132 may be equal to the bandgaps of the first confinement layer 120b and the second confinement layer 120c. For example, the bandgap size of each layer may be changed by adjusting the percentage of aluminum content (Al %) in each layer. For example, the percentages of aluminum content (Al %) of the first confinement layer 120b and the second confinement layer 120c are greater than the percentage of aluminum content (Al %) of the first barrier layer B₁, the second barrier layer B₂, the third barrier layer B₃ or the additional barrier layer 120d. The percentages of aluminum content (Al %) of the first semiconductor layer 112 and third semiconductor layer 132 are equal to the percentages of aluminum content (Al %) of first confinement layer 120b and second confinement layer 120c. In an embodiment, the percentages of aluminum content (Al %) of the first semiconductor layer 112 and the third semiconductor layer 132 may be in a range of 75% to 100%, the percentages of aluminum content (Al %) of the first confinement layer 120b and the second confinement layer 120c may be in a range of 75% to 100%, the percentages of aluminum content (Al %) of the first barrier layer B₁ and the additional barrier layer 120d may be in a range of 50% to 80%, and the percentages of aluminum content (Al %) of the second barrier layer B₂ and the third barrier layer B₃ may be in a range of 40% to 70%, that is, the bandgaps of the first confinement layer 120b, the first barrier layer B₁, and the second barrier layer B₂ can sequentially become smaller, and the bandgaps of the third barrier layer B₃, the additional barrier layer 120d, and the second confinement layer 120c can sequentially become larger, thereby making it easier for the carrier to move into the active region 120, improving the efficiency of carrier recombination, and improving the brightness of the semiconductor device 10.

FIG. 2D shows a schematic view of the energy band of the active region 120, the first semiconductor layer 112, and the third semiconductor layer 132 in the semiconductor device 10 according to an embodiment of the present disclosure. FIG. 2D also shows a light-emitting region 120a with three semiconductor stacks (i.e., an embodiment of N=3). The difference between the embodiments of FIG. 2D and FIG. 2C is that the bandgap of the first semiconductor layer 112 is greater than the bandgap of the first confinement layer 120b in FIG. 2C. For example, the bandgap size of each layer may be changed by adjusting the percentage of aluminum content (Al %) in each layer. For example, the percentage of aluminum content (Al %) of the first semiconductor layer 112 is greater than the percentage of aluminum content (Al %) of the first confinement layer 120b, and the percentage of aluminum content (Al %) of the first confinement layer 120b is greater than the percentage of aluminum content (Al %) of the first barrier layer B₁, the second barrier layer B₂ or the third barrier layer B₃, the percentage of aluminum content (Al %) of the third semiconductor layer 132 is equal to the percentage of aluminum content (Al %) of the second confinement layer 120c and is greater than the percentage of aluminum content (Al %) of the additional barrier layer 120d. As shown in FIG. 2D, in this embodiment, the active region 120 has a left-right asymmetric energy band structure. For example, when designating the second well layer W₂ as a center, the energy band structure on both sides of the second well layer W₂ is asymmetric. According to an embodiment, when the conductivity type of the first semiconductor layer 112 is n-type, the conductivity type of the third semiconductor layer 132 is p-type for respectively providing electrons and holes to the light-emitting region 120a, the movement rate of electrons can be higher than that of the holes thereby adopting the asymmetric energy band structure makes it easier for the electrons to move into the well layer(s) close to a side of the third semiconductor layer 132 and to recombine with the holes to emit light, and the carrier recombination efficiency may be further improved.

In an embodiment, the percentage of aluminum content (Al %) of the first semiconductor layer 112 may be in a range of 75% to 100%, the percentage of aluminum content (Al %) of the first confinement layer 120b may be in a range of 50% to 80%, the percentage of aluminum content (Al %) of the first barrier layer B₁, the second barrier layer B₂ or the third barrier layer B₃ may be in a range of 40% to 70%, and the percentage of aluminum content (Al %) of the additional barrier layer 120d may be In a range of 50% to 80%, the percentage of aluminum content (Al %) of the second confinement layer 120c and the third semiconductor layer 132 may be in a range of 75% to 100%, thereby making it easier for the carriers (such as electrons) on a side to move into the active region 120. When the movement rates of the electrons or holes are different, the left-right asymmetric energy band structure may help to improve the carrier recombination efficiency and further improve the brightness of the semiconductor device 10.

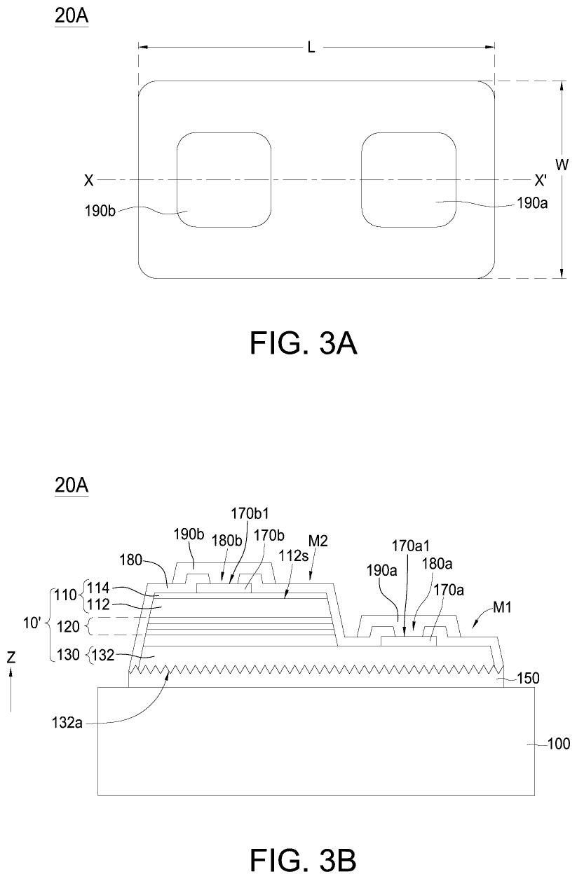

FIG. 3A shows a schematic top view of a semiconductor device 20A according to an embodiment of the present disclosure. FIG. 3B shows a schematic sectional view of the semiconductor device 20A of FIG. 3A along X-X′ line. As shown in FIG. 3B, the semiconductor device 20A includes a first semiconductor structure 110, an active region 120, a second semiconductor structure 130, a base 100 and an adhesive layer 150. In this embodiment, the base 100 is a bonding substrate, which is bonded to the second semiconductor structure 130 through the adhesive layer 150. In this embodiment, from a side close to the active region 120 to another side away from the active region 120, the first semiconductor structure 110 includes the first semiconductor layer 112 and the second semiconductor layer 114 in sequence. The second semiconductor structure 130 includes the third semiconductor layer 132. Regarding the material, thickness, and so on of each semiconductor layer, the description in the previous embodiments can be referred to. In this embodiment, the third semiconductor layer 132 can serve as a cladding layer and a contact layer at the same time.

In this embodiment, the adhesive layer 150 may be electrically insulating. In an embodiment, the material of the adhesive layer 150 includes a polymer material, such as benzocyclobutene (BCB), epoxy resin, polyimide, or silicone resin, or an oxide, such as aluminum oxide (Al₂O₃) or silicon oxide (SiO₂). As shown in FIG. 3B, a lower surface 132a of the third semiconductor layer 132 has a concave and convex structure, thereby a stable bonding structure can be easily formed between the third semiconductor layer 132 and the adhesive layer 150.

As shown in FIG. 3B, the appearance of the semiconductor device 20A (e.g., the overall appearance formed by the first semiconductor structure 110, the active region 120 and the second semiconductor structure 130) has a first mesa structure M1 and a second mesa structure M2. Specifically, relative to an upper surface of the base 100, an upper surface of the second mesa structure M2 may be higher than an upper surface of the first mesa structure M1. The semiconductor device 20A may further include a first conductive structure 170a and a second conductive structure 170b. Specifically, the first conductive structure 170a and the second conductive structure 170b are respectively in direct contact with the first semiconductor structure 110 and the second semiconductor structure 130 to form electrical connections. As shown in FIG. 3B, the first conductive structure 170a may be located on the first mesa structure M1 and may be in direct contact with the third semiconductor layer 132. The second conductive structure 170b may be located on the second mesa structure M2 and may be in direct contact with the second semiconductor layer 114. The materials of the first conductive structure 170a and the second conductive structure 170b may be selected according to the materials of the semiconductor layers in direct contact with them to form good electrical contacts (such as ohmic contacts). According to some embodiments, the materials of the first conductive structure 170a and the second conductive structure 170b may include metal or alloy. Examples of the metal include germanium (Ge), beryllium (Be), zinc (Zn), gold (Au), nickel (Ni) or copper (Cu). The alloy may include two or more of the above metals, such as germanium gold nickel (GeAuNi), beryllium gold (BeAu), germanium gold (GeAu), or zinc gold (ZnAu). The materials of the first conductive structure 170a and the second conductive structure 170b may be different or the same. According to an embodiment, the first conductive structure 170a includes beryllium gold (BeAu), and the second conductive structure 170b includes germanium gold (GeAu).

As shown in FIG. 3B, the semiconductor device 20A may optionally include an insulating structure 180 which may cover the first semiconductor structure 110, the active region 120 and the second semiconductor structure 130, and may further cover the adhesive layer 150 and/or the base 100. The insulating structure 180 may cover a portion of an upper surface 170al of the first conductive structure 170a and cover a portion of an upper surface 170b1 of the second conductive structure 170b. The insulating structure 180 may have a first hole 180a and a second hole 180b. The first hole 180a and the second hole 180b respectively correspond to the positions of the first conductive structure 170a and the second conductive structure 170b in a vertical direction Z. The insulating structure 180 may isolate external moisture or pollution and prevent the epitaxial structure from being damaged. The insulating structure 180 may include a dielectric material, such as aluminum oxide (AlOₓ), silicon oxide (SiOₓ), titanium oxide (TiOₓ), silicon nitride (SiNₓ), or a combination thereof. In an embodiment, the insulating structure 180 may further have a reflective function. For example, the insulating structure 180 may include a Distributed Bragg Reflector (DBR) structure. When the insulating structure 180 has the reflective function, the light emitted by the active region 120 may be mainly emitted from the lower surface 132a side of the third semiconductor layer 132. According to some embodiments, a width of the second semiconductor layer 114 in the semiconductor device 20A may be less than or equal to the width of the second conductive structure 170b, that is, the second semiconductor layer 114 may just cover a portion of the upper surface 112s of the first semiconductor layer 112, and another portion of the upper surface 112s is in direct contact with the insulating structure 180, thereby reducing absorption of the light emitted from the active region 120 by the material of the second semiconductor layer 114.

The semiconductor device 20A may further include a first electrode 190a and a second electrode 190b. As shown in FIG. 3B, the first electrode 190a fills the first hole 180a and is in direct contact with the first conductive structure 170a; the second electrode 190b fills the second hole 180b and is in direct contact with the second conductive structure 170b. The first electrode 190a and the second electrode 190b respectively include a single-layer structure or a multi-layer structure. For example, the first electrode 190a and the second electrode 190b each includes metal, such as nickel (Ni), titanium (Ti), platinum (Pt), palladium (Pd), silver (Ag), gold (Au), aluminum (Al), tin (Sn), copper (Cu) or a combination thereof. In an embodiment, an upper surface of the first electrode 190a and an upper surface of the second electrode 190b may have approximately the same height. As shown in FIG. 3A, when viewed from above, each of the first electrode 190a and the second electrode 190b may have a shape of a rectangle with rounded corners.

As shown in FIG. 3A, the semiconductor device 20A may have a length L and a width W when viewed from above. In some embodiments, the length L and the width W each may be less than or equal to 500 μm, for example, less than or equal to 450 μm, 400 μm, 350 μm, 300 μm, 250 μm, 200 μm, 150 μm, 100 μm, 50 μm, 30 μm. or 10 μm, and may be greater than or equal to 1 μm. When viewed from above, the semiconductor device 20A may be rectangular. In an embodiment, the length L and the width W of the semiconductor device 20A may be approximately equal and may be square or circular. In an embodiment, when viewed from above, the area (L*W) of the upper surface of the semiconductor device 20A is 10000 μm² or less, for example, in a range of 1 μm² to 5000 μm² (such as 100 μm², 625 μm², 1250 μm², 2000 μm² or 2500 μm²). In an embodiment, when viewed from above, a diagonal length of the semiconductor device 20A may be greater than 1 μm and less than 100 μm. The detailed descriptions of positions, relative relationships and material of other layers or structures as well as structural variations in this embodiment can be referred to the foregoing embodiments and are not repeatedly described herein.

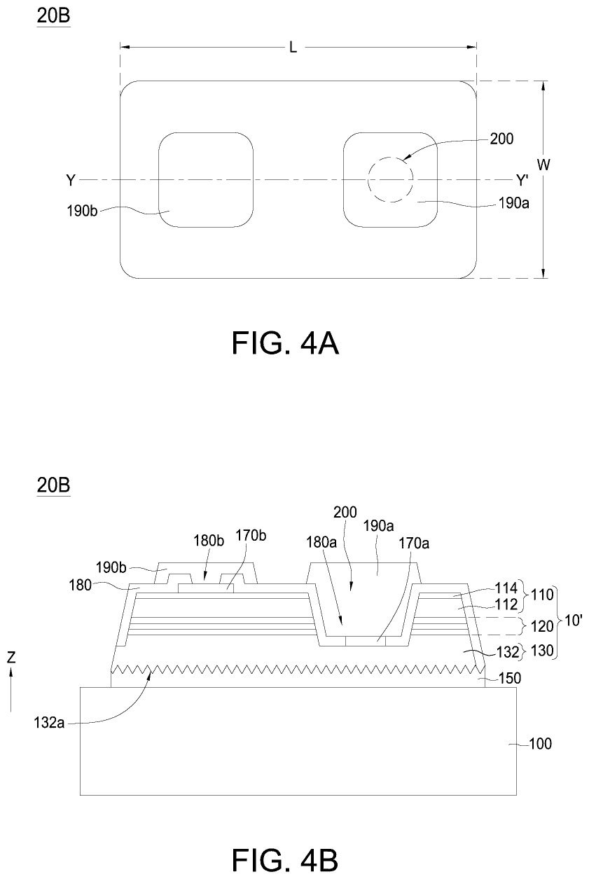

FIG. 4A shows a schematic top view of a semiconductor device 20B according to an embodiment of the present disclosure. FIG. 4B shows a schematic sectional view of the semiconductor device 20B of FIG. 4A along Y-Y′ line. As shown in FIG. 4A, the main difference between the semiconductor device 20B and the semiconductor device 20A is that the epitaxial structure 10′ (i.e., the first semiconductor structure 110, the active region 120 and the second semiconductor structure 130) of the semiconductor device 20B has a recess portion 200, and the third semiconductor layer 132 is exposed at the bottom of the recess portion 200. The top-view shape of the recess portion 200 may be circular, elliptical, rectangular or other polygonal shape. The insulating structure 180 may also cover a side wall of the recess portion 200. Similarly, in this embodiment, the first electrode 190a fills the first hole 180a and is in direct contact with the first conductive structure 170a; the second electrode 190b fills the second hole 180b and is in direct contact with the second conductive structure 170b.

In some embodiments, the adhesive layer 150 may be used as a release layer. For example, the base 100 and the structure on the base 100 may be separated by etching, laser stripping, heating the adhesive layer 150 or performing UV light treatment on the adhesive layer 150. The semiconductor device 20A or the semiconductor device 20B may not have the adhesive layer 150 and/or the base 100. The upper surfaces of the first electrode 190a and the upper surfaces of the second electrode 190b in the semiconductor device 20A and the semiconductor device 20B are located on the same side of the active region 120, that is, the semiconductor device 20A and the semiconductor device 20B are horizontal type devices. The detailed descriptions of positions, relative relationships and material of other layers or structures as well as structural variations in this embodiment can be referred to the foregoing embodiments and are not repeatedly described herein.

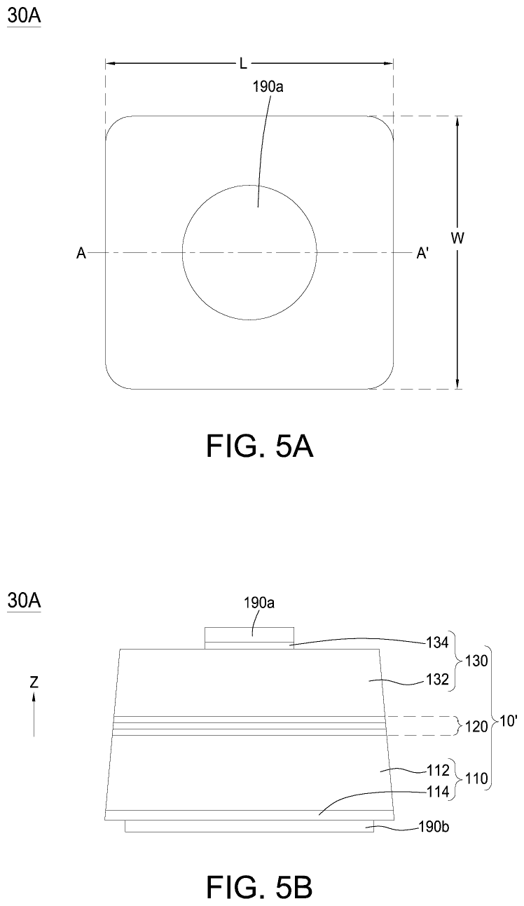

FIG. 5A shows a schematic top view of a semiconductor device 30A according to an embodiment of the present disclosure. FIG. 5B shows a schematic sectional view of the semiconductor device 30A of FIG. 5A along A-A′ line. As shown in FIG. 5A, the semiconductor device 30A includes a first semiconductor structure 110, an active region 120, a second semiconductor structure 130, a first electrode 190a and a second electrode 190b. In this embodiment, unlike the semiconductor device 20A and the semiconductor device 20B, the upper surface of the first electrode 190a and the upper surface of the second electrode 190b are located on different sides of the active region 120, that is, the semiconductor device 30A is a vertical type device. The semiconductor device 30A may optionally include a first conductive structure 170a located between the second semiconductor structure 130 and the first electrode 190a (not shown), and may optionally include a second conductive structure 170b located between the first semiconductor structure 110 and the second electrode 190b (not shown). As shown in FIG. 5A, when viewed from above, the first electrode 190a can cover a geometric center of the upper surface of the semiconductor device 30A. As shown in FIG. 5B, the first electrode 190a and the second electrode 190b overlap in the vertical direction Z. In an embodiment, the semiconductor device 30A may optionally include a base 100 which is conductive and located below the first semiconductor structure 110 (not shown).

As shown in FIG. 5B, from a side close to the active region 120 to another side away from the active region 120, the first semiconductor structure 110 includes a first semiconductor layer 112 and a second semiconductor layer 114 in sequence. From a side close to the active region 120 to another side away from the active region 120, the second semiconductor structure 130 includes a third semiconductor layer 132 and a fourth semiconductor layer 134 in sequence. In an embodiment, a portion of an upper surface of the third semiconductor layer 132 that is not covered by the first electrode 190a may further have a roughened structure to improve light extraction efficiency. The detailed descriptions of positions, relative relationships and material of other layers or structures as well as structural variations in this embodiment can be referred to the foregoing embodiments and are not repeatedly described herein.

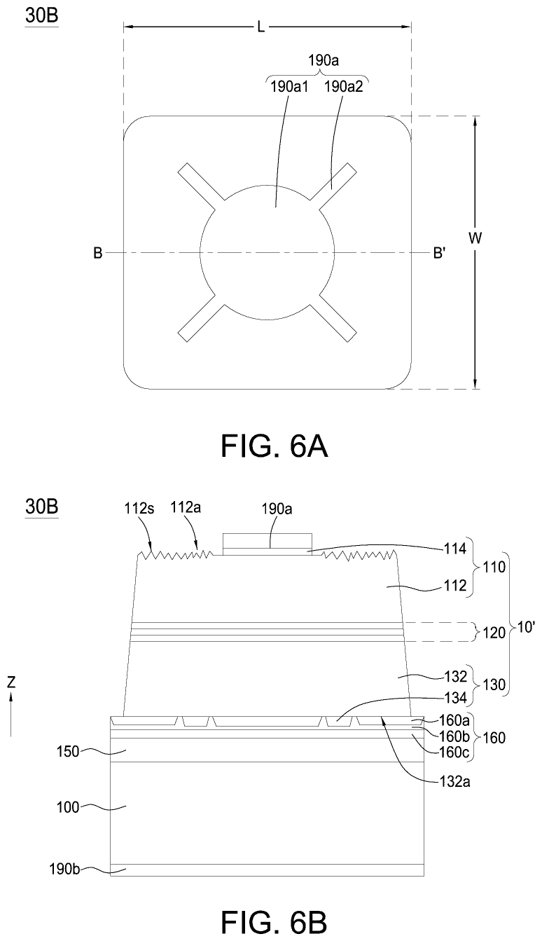

FIG. 6A shows a schematic top view of a semiconductor device 30B according to an embodiment of the present disclosure. FIG. 6B shows a schematic sectional view of the semiconductor device 30B of FIG. 6A along B-B′ line. As shown in FIG. 6A and FIG. 6B, the semiconductor device 30B includes a first semiconductor structure 110, an active region 120, a second semiconductor structure 130, a base 100, an adhesive layer 150 and a reflective structure 160. The reflective structure 160 may be located between the adhesive layer 150 and the first semiconductor structure 110. The reflective structure 160 may include an insulating layer 160a, a conductive layer 160b, and a metal reflective layer 160c. In this embodiment, the fourth semiconductor layer 134 may be a patterned contact layer. As shown in FIG. 6B, the fourth semiconductor layer 134 and the insulating layer 160a are located on the lower surface 132a of the third semiconductor layer 132 and are in direct contact with the third semiconductor layer 132. According to some embodiments, the fourth semiconductor layer 134 and the insulating layer 160a may be in direct contact or separated by a distance. The conductive layer 160b covers the fourth semiconductor layer 134 and the insulating layer 160a, and is in direct contact with the fourth semiconductor layer 134 to form a conductive path. The conductive layer 160b may include a metal oxide, such as indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). The metal reflective layer 160c is located between the conductive layer 160b and the adhesive layer 150. The metal reflective layer 160c may have a reflectivity of 80% or more relative to the light emitted from the active region 120. The metal reflective layer 160c may include metal, such as silver (Ag), gold (Au) or aluminum (Al).

The semiconductor device 30B may further include a first electrode 190a and a second electrode 190b. The first electrode 190a includes an electrode pad 190al and a plurality of extension electrodes 190a2. The plurality of extension electrodes 190a2 connect to the electrode pad 190al and may extend from the electrode pad 190al to an edge of the semiconductor device 30B. The electrode pad 190al can serve as an electrical connection point for connecting an external power source or other devices. The plurality of extension electrodes 190a2 may be separated from each other. In an embodiment, the first electrode 190a and the fourth semiconductor layer 134 may not overlap in the vertical direction Z to further improve current diffusion in the semiconductor device 30B.

In this embodiment, the base 100 is a conductive bonding substrate, which is bonded to the second semiconductor structure 130 through the adhesive layer 150. In this embodiment, the adhesive layer 150 is conductive, and the adhesive layer 150 may include metal, such as gold (Au) or indium (In). According to an embodiment, the melting point of the material used to form the adhesive layer 150 may be lower than 400° C., so as to facilitate bonding the base 100 and the metal reflective layer 160c by welding, eutectic or thermocompression process, for example. In this embodiment, from a side close to the active region 120 to another side away from the active region 120, the first semiconductor structure 110 includes a first semiconductor layer 112 and a second semiconductor layer 114 in sequence. From a side close to the active region 120 to another side away from the active region 120, the second semiconductor structure 130 includes a third semiconductor layer 132 and a fourth semiconductor layer 134 in sequence. As shown in FIG. 6B, a portion of the upper surface 112s of the first semiconductor layer 112 that is not covered by the first electrode 190a may further have a roughened structure 112a to improve the light extraction efficiency. The detailed descriptions of positions, relative relationships and material of other layers or structures as well as structural variations in this embodiment can be referred to the foregoing embodiments and are not repeatedly described herein.

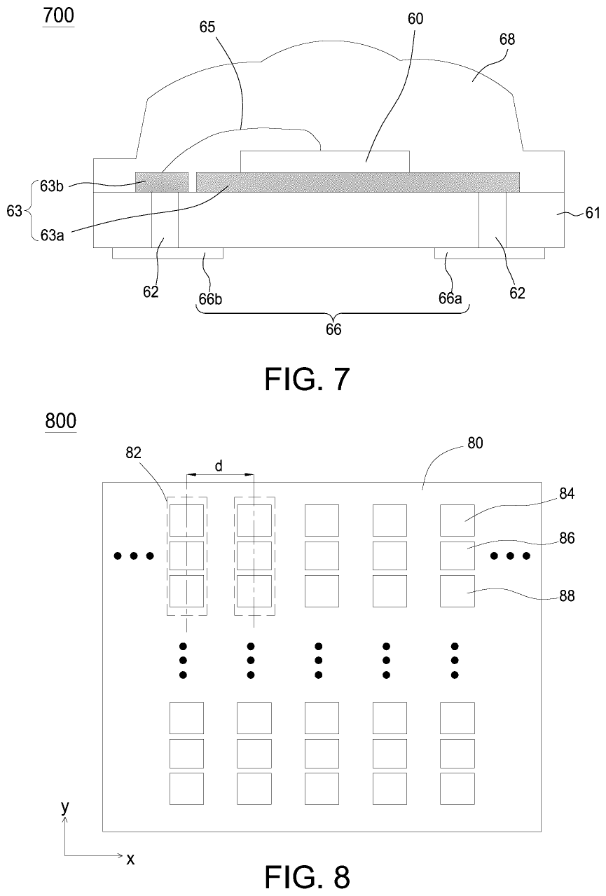

FIG. 7 shows a schematic sectional view of a semiconductor component 700 in accordance with an embodiment of the present disclosure. As shown in FIG. 7, the semiconductor component 700 includes a semiconductor device 60, a package substrate 61, a carrier 63, a bonding wire 65, a contact structure 66 and an encapsulating material 68. The package substrate 61 may include a ceramic or glass. The package substrate 61 has a plurality of through holes 62. Each through hole 62 may be filled with a conductive material such as metal for electrical conduction and/or heat dissipation. The carrier 63 may be located on a surface of one side of the package substrate 61 and may contain a conductive material such as metal. The contact structure 66 is on a surface of another side of the package substrate 61. In the embodiment, the contact structure 66 includes a first contact pad 66a and a second contact pad 66b, and the first contact pad 66a and the second contact pad 66b can be electrically connected to the carrier 63 through the through holes 62. In an embodiment, the contact structure 66 may further include a thermal pad (not shown), for example, between the first contact pad 66a and the second contact pad 66b.

The semiconductor device 60 is located on the carrier 63 and may be the semiconductor device as described in any embodiment of the present disclosure (such as the semiconductor devices 10, 10A, 10B, 30A or 30B). In the embodiment, the carrier 63 includes a first portion 63a and a second portion 63b, and the semiconductor device 60 is electrically connected to the second portion 63b of the carrier 63 by a bonding wire 65. The bonding wire 65 may include metal, such as gold (Au), silver (Ag), copper (Cu), or aluminum (Al), or may include alloy containing one or more of the above metals. The encapsulating material 68 covers the semiconductor device 60 and protects the semiconductor device 60. Specifically, the encapsulating material 68 may include a resin material, such as an epoxy resin, or a silicone resin. The encapsulating material 68 may further include a plurality of wavelength conversion particles to convert a first light emitted by the semiconductor device 60 into a second light. The wavelength of the second light is greater than the wavelength of the first light.

FIG. 8 shows a schematic sectional view of a semiconductor component 800 in accordance with an embodiment of the present disclosure. The semiconductor component 800 of the embodiment is, for example, a display. As shown in FIG. 8, the semiconductor component 800 includes a carrier board 80 and a plurality of pixel units 82 on the carrier board 80. The plurality of pixel units 82 are arranged in an array along the directions parallel to the x-axis and the y-axis, and are arranged at an interval d in the direction parallel to the x-axis. The number of pixel units 82 can be adjusted based on actual needs. For example, in an embodiment, a display with a resolution of 1920×1080 pixels can be provided by the plurality of pixel units 82 included in the semiconductor component 800. In an embodiment, the interval d is less than 1.4 mm, for example, the interval d is in a range of 0.2 mm to 1.3 mm, such as 0.75 mm, 0.8 mm, 1 mm or 1.25 mm. As shown in FIG. 8, each pixel unit 82 includes a first semiconductor device 84, a second semiconductor device 86, and a third semiconductor device 88 arranged in a direction parallel to the y-axis. One or more of the first semiconductor device 84, the second semiconductor device 86, and the third semiconductor device 88 is the semiconductor device described in any embodiment of the present disclosure (such as the semiconductor device 10, 10A, 10B, 20A, 20B, 30A or 30B). In an embodiment, the first semiconductor device 84, the second semiconductor device 86, and the third semiconductor device 88 are all light-emitting devices and can emit red light, green light, and blue light, respectively. In an embodiment, the arrangement order of the light-emitting devices can also be adjusted based on actual needs. For example, the first semiconductor device 84, the second semiconductor device 86, and the third semiconductor device 88 emit red light, blue light, and green light, respectively. Each pixel unit 82 can be electrically connected to a circuit (not shown) on the surface of the carrier board 80, so that the light-emitting devices therein can receive an external signal and emit light in accordance with the external signal. The carrier board 80 may have a single-layer or multi-layer structure. In an embodiment, the material of the carrier board 80 includes a polyester, polyimide (PI), BT (Bismaleimide Triazine) resin, PTFE (Polytetrafluoroethylene) resin, phenol resin (PF) or glass fiber epoxy resin (such as FR4). In an embodiment, the carrier board 80 can be bent, and for example, can withstand a radius of curvature less than 50 mm, such as 25 mm or 32 mm.

Based on the above, a semiconductor device and a semiconductor component are provided in the present disclosure. For example, optoelectronic properties (such as EQE) of the semiconductor device or the semiconductor component can be improved. Specifically, the semiconductor device and the semiconductor component of the present disclosure can be applied to products in various fields, such as illumination, display, communication or power supply system, for example, can be used in a light fixture, monitor, an automotive instrument panel, a television, computer, traffic sign, or an outdoor display device.

It should be realized that each of the embodiments mentioned in the present disclosure is used for describing the present disclosure, but not for limiting the scope of the present disclosure. Any obvious modification or alteration is not departing from the spirit and scope of the present disclosure. Furthermore, embodiments may be combined or substituted under proper condition and are not limited to specific embodiments described above. A connection relationship between a specific component and another component specifically described in an embodiment can also be applied in another embodiment and is within the scope as claimed in the present disclosure.

What is claimed is:

1. A semiconductor device, comprising:
a first semiconductor structure;
a second semiconductor structure; and
an active region between the first semiconductor structure and the second semiconductor structure; wherein the active region comprises a light-emitting region having N pair(s) of semiconductor stack(s), each of the semiconductor stack comprises a well layer and a barrier layer, in which N is a positive integer greater than or equal to 1, wherein the well layer comprises a first group III-V semiconductor material comprising indium with a first percentage of indium content, the barrier layer comprises a second group III-V semiconductor material comprising indium with a second percentage of indium content, the first group III-V semiconductor material and the second group III-V semiconductor material further comprises phosphorus, and the second percentage of indium content is less than the first percentage of indium content.

2. The semiconductor device of claim 1, wherein the first percentage of indium content is greater than or equal to 55%.

3. The semiconductor device of claim 1, wherein a difference between the first percentage of indium content and the second percentage of indium content is greater than or equal to 10%.

4. The semiconductor device of claim 1, wherein the barrier layer has a first thickness, the well layer has a second thickness, and the first thickness is at least 2.5 times the second thickness.

5. The semiconductor device of claim 1, wherein N is less than or equal to 5.

6. The semiconductor device of claim 1, wherein the first group III-V semiconductor material and the second group III-V semiconductor material are the same.

7. The semiconductor device of claim 6, wherein the first group III-V semiconductor material and the second group III-V semiconductor material are quaternary group III-V semiconductor compound.

8. The semiconductor device of claim 7, wherein the first group III-V semiconductor material and the second group III-V semiconductor material are AlGaInP.

9. The semiconductor device of claim 1, wherein the barrier layer has a first thickness greater than or equal to 100 Å.

10. The semiconductor device of claim 1, wherein the well layer has a second thickness less than or equal to 50 Å.

11. The semiconductor device of claim 1, wherein the first semiconductor structure comprises a first semiconductor layer having a dopant concentration less than 3×10¹⁸ cm⁻³.

12. The semiconductor device of claim 1, further comprising a base located under the first semiconductor structure.

13. The semiconductor device of claim 12, wherein the well layer and the base are lattice-mismatched.

14. The semiconductor device of claim 1, wherein the first percentage of indium content is in a range of 55% to 85%, and the second percentage of indium content is in a range of 45% to 55%.

15. The semiconductor device of claim 1, wherein the first group III-V semiconductor material comprises gallium with a first percentage of gallium content, the second group III-V semiconductor material comprises gallium with a second percentage of gallium content greater than the first percentage of gallium content.

16. The semiconductor device of claim 15, wherein the first percentage of gallium content is greater than or equal to 25%.

17. The semiconductor device of claim 1, wherein the active region further comprises a first confinement layer and a second confinement layer, and the light-emitting region is located between the first confinement layer and the second confinement layer.

18. The semiconductor device of claim 17, wherein the first confinement layer has a third thickness which is at least 2 times the first thickness.

19. The semiconductor device of claim 17, wherein the active region further comprises an additional barrier layer located between the light-emitting region and the second confinement layer.

20. The semiconductor device of claim 17, wherein the first confinement layer comprising aluminum with a first percentage of aluminum content in a range of 75% to 100%.
